(19) United States
(12) Patent Application Publication
(10) Pub. No.: US 2013/0096859 A1
(43) Pub. Date: Apr. 18, 2013

(54) RESISTANCE DETERMINING SYSTEM

(71) Applicants: QI-YAN LUO, Shenzhen City (CN); SONG-LIN TONG, Shenzhen City (CN)

(72) Inventors: QI-YAN LUO, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/594,853

(22) Filed: Aug. 26, 2012

(30) Foreign Application Priority Data
Oct. 14, 2011 (CN) 201110311434.X

(51) Int. Cl. G01R 27/08; G06F 19/00

(52) U.S. Cl. 702/65; 324/705

(57) ABSTRACT

A resistance determining device configured for determining a resistance for a digital power supply control microchip includes a digital potentiometer and a controller. The digital potentiometer is electrically connected to the digital power supply control microchip. The controller is electrically connected to the digital potentiometer. The controller obtains internal current and load current of the digital power supply control microchip, compares the internal current with the load current, and changes a current resistance of the digital potentiometer to be a resistance according to a difference between the internal current and the load current. The resistance makes the internal current consistent with the load current.

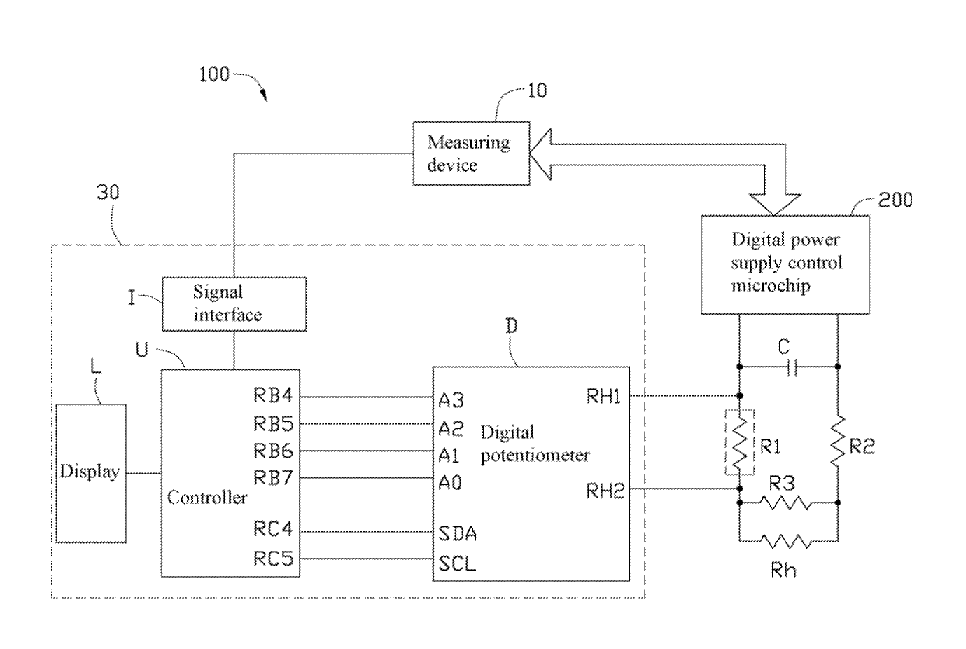

### BACKGROUND

1. Technical Field

The disclosure generally relates to resistance determining systems, and particularly to a resistance determining system used to determine a resistance of a resistor of a digital power supply control microchip.

2. Description of Related Art

During use, a digital power supply control microchip provides a working voltage for a central processing unit (CPU), and internal current of the digital power supply control microchip commonly needs to be verified according to load current of the digital power supply control microchip. In a typical current verifying method a first test program measures load current of the digital power supply control microchip as a basis current. A second test program measures internal current of the digital power supply control microchip. Resistors having different resistances are manually changed for the digital power supply control microchip to determine a suitable resistance which can make the internal current consistent with the load current.

However, a large number of resistors may be tried before the suitable resistance is determined, which may use much time and be expensive.

In view of the above, there is room for improvement within the art.

### BRIEF DESCRIPTION OF THE DRAWING

Many aspects of the present disclosure can be better understood with reference to the following drawing. The components in the drawings are not necessarily drawn to scale, the emphasis instead being placed upon clearly illustrating the principles of the disclosure.

The FIGURE is a block diagram of a resistance determining system, according to an exemplary embodiment of the disclosure.

### DETAILED DESCRIPTION

The FIGURE is a block diagram of a resistance determining system 100, according to an exemplary embodiment of the disclosure. The system 100 is configured for determining a resistance of a current resistor for a digital power supply control microchip 200. The system 100 includes a measuring device 10 and a resistance determining device 30.

In one embodiment, the digital power supply control microchip 200 is a pulse width modulation (PWM) controller configured for providing a working voltage for a CPU (not shown). The digital power supply control microchip 200 is electrically connected to a peripheral circuit. The peripheral circuit includes a capacitor C, a first resistor R1, a second resistor R2, a third resistor R3 and a temperature compensating resistor Rh. The capacitor C is electronically connected to two ends of the digital power supply control microchip 200. The third resistor R3 and the temperature compensating resistor Rh are electrically connected in parallel, and connected to two ends of the digital power supply control microchip 200 via the first resistor R1 and the second resistor R2. The first resistor R1 serves as the current resistor of the digital power supply control microchip 200. Internal current of the digital power supply control microchip 200 can be verified by changing resistance of the first resistor R1.

In one embodiment, the measuring device 10 is a computer. The measuring device 10 includes a first test program and a second test program installed in the measuring device 10. The measuring device 10 is electrically connected to the digital power control microchip 200 by an I2C data bus. The measuring device 10 measures load current (i.e. current output from the digital power control microchip 200 to a load) and the internal current of the digital power control microchip 200 by the first test program and the second test program. The load current and the internal current value can be both displayed by the measuring device 10.

The resistance determining device 30 includes a controller U, a signal interface I, a digital potentiometer D and a display L. The signal interface I, the digital potentiometer D and the display L are electrically connected to the controller U.

The controller U can be a single chip microcomputer. The controller U is electrically connected to the measuring device 10 by the signal interface I to obtain the internal electrical current and the load electrical current of the digital power supply control microchip 200. The signal interface I may be a MAX232 interface or a USB interface. The controller U compares the internal current with the load current, determines a corresponding adjusted resistance according to a difference between the internal current and the load current, and changes a current resistance of the digital potentiometer D by the adjusted resistance. Thus, the current resistance of the digital potentiometer D is changed to be a resistance of the first resistor R1.

The controller U includes a plurality of initial contacts RB4, RB5, RB6, and RB7, a first data contact RC4 and a first clock contact RC5 electrically connected to the digital potentiometer D. The initial contacts RB4, RB5, RB6 are configured for initializing the digital potentiometer D so that the controller U can establish a communication with the digital potentiometer D. The first data contact RC4 is configured for transmitting the adjusted resistance to the digital potentiometer D to change the current resistance of the digital potentiometer D and also receiving the current resistance of the digital potentiometer D from the digital potentiometer D. The clock contact RC5 is configured for transmitting a synchronous clock signal to the digital potentiometer D.

The digital potentiometer D includes a plurality of address contacts A0, A1, A2, and A3, a second data contact SDA, a second clock contact SCL and a pair of verifying contacts RH1 and RH2. The address contact A0, A1, A2, and A3 are electrically connected to the initial contacts RB7, RB6, RB5, and RB4 to execute an initialing process. The second data contact SDA is electrically connected to the first data contact RC4. The second data contact SDA receives the adjusted resistance from the first data contact RC4 thereby changing the current resistance of the current digital potentiometer D. The second data contact SDA also transmits the current resistance of the digital potentiometer D as the resistance to the first data contact RC4. The second clock contact SCL is electrically connected to the first clock contact RC5 to receive the synchronous clock signal. The verifying contacts RH1 and RH2 are electrically connected to two ends of the first resistor R1 so that when the first resistor R1 is disconnected from the peripheral circuit, the digital potentiometer D replaces the first resistor R1 as the resistor.

The display L is electrically connected to the controller U. The controller U controls the display L to display the resistance.

To determine resistance for the digital power supply control microchip 200, the first resistor R1 is disconnected from the peripheral circuit, and the resistance measuring contacts RH1, RH2 are electrically connected to the peripheral circuit similar to the first resistor R1 and replacing the first resistor R1. The controller U obtains the internal current and the load current and determines the adjusted resistance according the difference between the internal current and the load current. The adjusted resistance is transmitted to the digital potentiometer D by the first data contact RC4 and second data contact SDA. The current resistance of the digital potentiometer D can be changed based on the adjusted resistance and makes the internal current consistent with the load current. The current resistance of the digital potentiometer D is determined as the resistance and transmitted to the controller U. The controller U controls the display L to display the resistance. Thus, the first resistor R1 having the resistance can be electrically connected to the peripheral circuit to verify the internal current of the digital potentiometer D.

In other embodiment, the display L can be omitted. A speaker can be added to electrically connect to the controller U. The speaker can output an audio signal of the resistance.

The resistance determining device 30 can determine the resistance by the controller U and avoid changing the first resistor R1 many times which is more convenient.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A resistance determining device configured for determining resistance of a digital power supply control microchip, the device comprising:
a digital potentiometer electrically connected to the digital power supply control microchip;
a controller electrically connected to the digital potentiometer, the controller obtaining internal current and load current of the digital power supply control microchip, comparing the internal current with the load current, and changing a current resistance of the digital potentiometer to be a resistance according to a difference between the internal current and the load current; wherein the resistance makes the internal current consistent with the load current.

2. The device of claim 1, wherein the digital potentiometer comprises a plurality of address contacts, the controller comprises a plurality of initial contacts electrically connected to the address contacts to initialize the digital potentiometer.

3. The device of claim 1, wherein the controller determines an adjusted resistance according to the difference between the internal current and the load current, and transmits the adjusted resistance to the digital potentiometer to change the resistance of the digital potentiometer.

4. The device of claim 3, wherein the controller comprises a first data contact, the digital potentiometer comprises a second data contact electrically connected to the first data contact, the controller transmits the adjusted resistance to the digital potentiometer by the first data contact and the second data contact.

5. The device of claim 4, wherein the controller receives the current resistance of the digital potentiometer by the first data contact and the second data contact.

6. The device of claim 5, further comprising a display electrically connected to the controller, the display displays the current resistance.

7. A resistance determining system configured for determining a resistance for a digital power supply control microchip, the system comprising:
a measuring device electrically connected to the digital power supply control microchip, the measuring device measuring internal current and load current of the digital power supply control microchip; and
a resistance determining device, the device comprising:
a digital potentiometer electrically connected to the digital power supply control microchip;
a controller electrically connected to the digital potentiometer, the controller obtaining internal current and load current of the digital power supply control microchip, comparing the internal current with the load current, and changing a current resistance of the digital potentiometer to be a resistance according to a difference between the internal current and the load current; wherein the resistance makes the internal current consistent with the load current.

8. The system of claim 7, wherein the digital potentiometer comprises a plurality of address contacts, the controller comprises a plurality of initial contacts electrically connected to the address contacts to initialize the digital potentiometer.

9. The system of claim 7, wherein the controller determines an adjusted resistance according to the difference between the internal current and the load current, and transmits the adjusted resistance to the digital potentiometer to change the resistance of the digital potentiometer.

10. The system of claim 9, wherein the controller comprises a first data contact, the digital potentiometer comprises a second data contact electrically connected to the first data contact, the controller transmits the adjusted resistance to the digital potentiometer by the first data contact and the second data contact.

11. The system of claim 10, wherein the controller receives the current resistance of the digital potentiometer by the first data contact and the second data contact.

12. The system of claim 11, wherein the resistance determining device further comprises a display electrically connected the controller, the display displays the current resistance.

13. The system of claim 7, wherein the measuring device is a computer.
